(19) United States
(12) Patent Application Publication
(10) Pub. No.: US 2025/0323225 A1
(43) Pub. Date: Oct. 16, 2025

(54) SEMICONDUCTOR MODULE AND METHOD FOR MANUFACTURING SAME

(71) Applicant: UltraMemory Inc., Tokyo (JP)

(72) Inventor: Kazuhiko KAJIGAYA, Tokyo (JP)

(21) Appl. No.: 18/866,464

(22) PCT Filed: May 18, 2022
(86) PCT No.: PCT/JP2022/020705

§ 371 Date: Nov. 15, 2024

(51) Int. Cl. H01L 25/10; H01L 21/48; H01L 23/00; H01L 23/498; H01L 25/065; H01L 25/18; H10B 80/00; H10D 80/30

(52) U.S. Cl. CPC H01L 25/105; H01L 21/4857; H01L 23/49811; H01L 24/48; H01L 25/0657; H01L 25/18; H01L 2224/48227; H01L 2225/0651; H01L 2225/06562; H10B 80/00; H10D 80/30

(57) ABSTRACT

A method for manufacturing a semiconductor module that includes a plurality of chips includes a first chip arrangement step for arranging a first chip; a rewiring layer formation step for forming a rewiring layer that is disposed on one surface side of the first chip and that is electrically connected to a second chip; a second chip arrangement step for arranging the second chip on the other surface side of the rewiring layer, the other surface side being opposite to the rewiring layer surface facing the first chip, at a position overlapping the first chip in the opposing direction; a pillar formation step for forming a pillar that extends from the other surface of the rewiring layer; and a substrate arrangement step for arranging a substrate that is electrically connected to the pillar and the second chip.

### TECHNICAL FIELD

The present invention relates to a semiconductor module and a method for manufacturing the semiconductor module.

### BACKGROUND ART

Conventionally, a volatile memory (RAM) such as a dynamin random access memory (DRAM) has been known as a storage device. The DRAM is required to have a large capacity such that it can support high performance of an arithmetic device (hereinafter referred to as a logic chip) and an increase in a volume of data. For this reason, attempts have been made to increase the capacity by way of miniaturization of the memory (memory cell array, memory chip) and planar addition of cells. On the other hand, this type of increase in capacity is reaching its limit because of the miniaturization resulting in susceptibility to noise, an increase in the chip area, and other factors.

Therefore, in recent years, a technique for achieving a large capacity by way of a three-dimensional (3D) structure that is formed by stacking a plurality of planar memories has been developed. Furthermore, in response to an increase in a volume of data to be handled, attempts have been made to increase the speed of data communication between chips (a logic chip and a memory chip). For example, a semiconductor module has been known in which a logic chip and a DRAM are placed on top of each other (for example, see Non-Patent Document 1).

### CITATION LIST

### Non-Patent Document

Non-Patent Document 1: Taiwan Semiconductor Manufacturing Company R&D, 2016 IEEE 66th Electronic Components and Technology Conference (ECTC)

### DISCLOSURE OF THE INVENTION

### Problems to be Solved by the Invention

The semiconductor module of Patent Document 1 includes a system-on-a-chip (SOC) and a low power DDR (LPDDR) that are stacked in two stages. The SOC does not include bumps for flip chip. In this way, a thin semiconductor module is achieved. It is more favorable to achieve a configuration with which a semiconductor module can be made thinner.

The present invention has been achieved in view of the above-described circumstances, and an object of the present invention is to provide a semiconductor module having a reduced thickness and a method for manufacturing such a semiconductor module.

### Means for Solving the Problems

The present invention relates to a method for manufacturing a semiconductor module including a plurality of chips, the method including: a first chip disposing step of disposing a first chip; a redistribution layer forming step of forming a redistribution layer, the redistribution layer being disposed on one surface of the first chip and electrically connected to a second chip, and having one surface facing the first chip; a second chip disposing step of disposing the second chip at a position on an other surface of the redistribution layer opposite to the one surface facing the first chip, the position overlapping with the first chip in a facing direction; a pillar forming step of forming a pillar that extends from the other surface of the redistribution layer; and a substrate disposing step of disposing a substrate that is electrically connected to the pillar and the second chip.

Preferably, the first chip disposing step is performed after the redistribution layer forming step, and the second chip disposing step, the pillar forming step, and the substrate disposing step are performed after the first chip disposing step.

Preferably, the second chip disposing step and the pillar forming step are performed after the substrate disposing step, and the redistribution layer forming step and the first chip disposing step are performed after the second chip disposing step and the pillar forming step.

Preferably, the second chip disposing step and the pillar forming step are performed after the redistribution layer forming step, and the first chip disposing step and the substrate disposing step are performed after the second chip disposing step and the pillar forming step.

Preferably, the method further includes a connecting step of electrically connecting the first chip and the redistribution layer, the connecting step being performed subsequent to the first chip disposing step.

Preferably, the connecting step includes wire bonding the first chip and the redistribution layer.

Furthermore, the present invention relates to a semiconductor module with a plurality of chips, the semiconductor module including: a substrate; a second chip disposed on one surface of the substrate; a pillar extending from the one surface of the substrate; a redistribution layer disposed such that the second chip is interposed between the redistribution layer and the substrate, the redistribution layer being electrically connected to the pillar; a first chip disposed on one surface of the redistribution layer opposite to an other surface facing the second chip; and a connection terminal electrically connecting the one surface of the redistribution layer and the first chip.

Preferably, the connection terminal includes a bonding wire and a bonding pad.

### Effects of the Invention

The present invention provides a semiconductor module having a reduced thickness and a method for manufacturing such a semiconductor module.

### BRIEF DESCRIPTION OF THE DRAWINGS

FIG. 1 is a cross-sectional view illustrating a semiconductor module according to a first embodiment of the present invention;

FIG. 2 is a cross-sectional view illustrating one process of manufacturing the semiconductor module according to the first embodiment;

FIG. 3 is a cross-sectional view illustrating one process of manufacturing the semiconductor module according to the first embodiment;

FIG. 4 is a cross-sectional view illustrating one process of manufacturing the semiconductor module according to the first embodiment;

FIG. 5 is a cross-sectional view illustrating one process of manufacturing the semiconductor module according to the first embodiment;

FIG. 6 is a cross-sectional view illustrating one process of manufacturing a semiconductor module according to a second embodiment of the present invention;

FIG. 7 is a cross-sectional view illustrating one process of manufacturing the semiconductor module according to the second embodiment;

FIG. 8 is a cross-sectional view illustrating one process of manufacturing a semiconductor module according to a third embodiment of the present invention;

FIG. 9 is a cross-sectional view illustrating one process of manufacturing the semiconductor module according to the third embodiment;

FIG. 10 is a cross-sectional view illustrating one process of manufacturing the semiconductor module according to the third embodiment;

FIG. 11 is a cross-sectional view illustrating one process of manufacturing the semiconductor module according to the third embodiment;

FIG. 12 is a cross-sectional view illustrating one process of manufacturing the semiconductor module according to the third embodiment;

FIG. 13 is a cross-sectional view illustrating one process of manufacturing the semiconductor module according to the third embodiment;

FIG. 14 is a cross-sectional view illustrating one process of manufacturing the semiconductor module according to the third embodiment;

FIG. 15 is a cross-sectional view illustrating one process of manufacturing a semiconductor module according to a fourth embodiment of the present invention;

FIG. 16 is a cross-sectional view illustrating one process of manufacturing the semiconductor module according to the fourth embodiment;

FIG. 17 is a cross-sectional view illustrating one process of manufacturing the semiconductor module according to the fourth embodiment; and

FIG. 18 is a cross-sectional view illustrating one process of manufacturing the semiconductor module according to the fourth embodiment.

### PREFERRED MODE FOR CARRYING OUT THE INVENTION

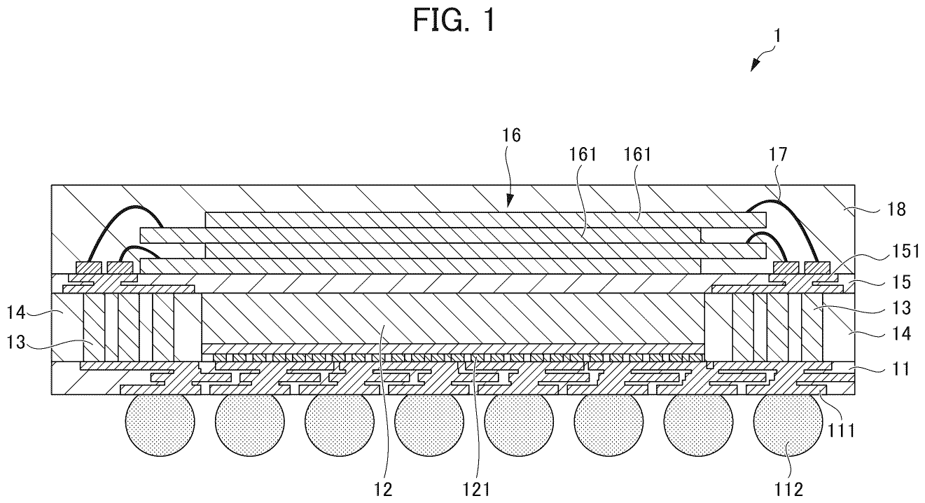

A semiconductor module 1 and a method for manufacturing the semiconductor module 1 according to each embodiment of the present invention will be described with reference to FIGS. 1 to 18. First, an outline of the semiconductor module 1 according to each embodiment will be described.

The semiconductor module 1 according to each embodiment includes, for example, a memory unit including a plurality of stacked memories and a logic chip (e.g., an SOC) are placed on top of each other. Specifically, in the semiconductor module 1, the memory unit and the logic chip are placed on top of each other in the stacking direction of the stacked memories. In the semiconductor module 1, the memory unit and the logic chip are placed on top of each other with a redistribution layer interposed therebetween, for example. The following embodiments approach thinning of the semiconductor module 1 by arranging the memory unit and the logic chip with the redistribution layer interposed therebetween. Furthermore, low-cost manufacture of the semiconductor module 1 is approached by manufacturing the memory unit and the logic chip at a wafer level. In the description of the following embodiments, the memory unit and the logic chip are referred to as a first chip and a second chip, respectively. For each component of the following embodiments, a surface or end closer to the upper side of FIG. 1 is referred to as one surface or one end, and a surface or end closer to the lower side of FIG. 1 is referred to as the other surface or the other end.

### First Embodiment

Next, a semiconductor module 1 and a method for manufacturing the same according to a first embodiment of the present invention will be described with reference to FIGS. 1 to 5. The semiconductor module 1 includes a plurality of chips. As illustrated in FIG. 1, the semiconductor module 1 includes a substrate 11, a second chip 12, pillars 13, a second mold portion 14, a redistribution layer 15, a first chip 16, connection terminals 17, and a first mold portion 18.

The substrate 11 is, for example, an organic substrate. The substrate 11 may be, for example, a redistribution layer. The substrate 11 is, for example, a plate-shaped body having a rectangular shape in plan view. The substrate 11 includes therein an electronic circuit 111, for example. The substrate 11 has one surface and the other surface opposite to the one surface, and is provided with, on the other surface, solder balls 112 for electrically connecting to another electronic circuit (not shown).

The second chip 12 is disposed on one surface of the substrate 11, for example. In the present embodiment, the second chip 12 is, for example, a logic chip (SOC). The second chip 12 is disposed on, and electrically connected to, the one surface of the substrate 11, for example. The second chip 12 is, for example, surface-mounted on the one surface of the substrate 11. The second chip 12 is surface-mounted on the one surface of the substrate 11 by way of, for example, a fan out wafer level package (FOWLP). The second chip 12 has, on the other surface thereof, terminal portions 121 for electrically connecting to the substrate 11.

The pillars 13 are made of a conductive material (e.g., copper). The pillars 13 extend from the one surface of the substrate 11. The pillars 13 extend, for example, from the one surface of the substrate 11 in an out-of-plane direction. The pillars 13 have, for example, a length equal to or greater than the thickness of the second chip 12. The pillars 13 are arranged around the second chip 12, for example. In the present embodiment, the pillars 13 are arranged along an in-plane direction of the one surface of the substrate 11 such that the second chip 12 is interposed therebetween. The pillars 13 each have one end electrically connected to the one surface of the substrate 11.

The second mold portion 14 is constituted by, for example, a mold resin. The second mold portion 14 is disposed on the one surface of the substrate 11. The second mold portion 14 has a thickness equal to the height (length) of the pillars 13, for example. The second mold portion 14 covers the second chip 12 and the pillar 13 on the one surface of the substrate 11. In plan view, the second mold portion 14 has an outer shape conforming to the substrate 11 that has a rectangular shape.

The redistribution layer 15 may be constituted by, for example, an organic substrate. The redistribution layer 15 includes therein an electronic circuit 151. The redistribution layer 15 is disposed such that the second chip 12 is interposed between the redistribution layer 15 and the substrate 11, and is electrically connected to the pillars 13. The redistribution layer 15 is disposed over the one surface of the substrate 11, for example. The redistribution layer 15 is disposed to extend over the second chip 12 and the pillars 13 in the in-plane direction of the one surface of the substrate 11. In the present embodiment, the redistribution layer 15 has, for example, a rectangular shape in plan view, likewise to the substrate 11. In plan view, the redistribution layer 15 has the same or substantially the same outer shape as the substrate 11 and the second mold portion 14. The redistribution layer 15 is disposed in a state of being electrically connected to the other end of each pillar 13. In the present embodiment, the redistribution layer 15 is disposed while having the other surface thereof in contact with one surface of the second chip 12. In plan view, the redistribution layer 15 has a rectangular shape conforming to the rectangular outer shape of the substrate 11.

The first chip 16 is disposed on one surface of the redistribution layer 15, which is opposite to the surface facing the second chip 12. In the present embodiment, the first chip 16 is, for example, a memory unit including a plurality of stacked memories 161. The first chip 16 includes, for example, the plurality of stacked memories 161 stacked in a stacking direction corresponding to an out-of-plane direction of the one surface of the redistribution layer 15. The first chip 16 includes the plurality of stacked memories 161 that are arranged out of alignment with respect to an in-plane direction of the one surface of the redistribution layer 15 (which is a direction intersecting with the stacking direction). The first chip 16 includes, for example, the plurality of stacked memories 161 that are adjacent to each other and arranged out of alignment with respect to the in-plane direction of the one surface of the redistribution layer 15. In the present embodiment, the first chip 16 includes the plurality of stacked memories 161 that are stacked in sequence in staggered positions on one side in the in-plane direction of the redistribution layer 15, for example.

The connection terminals 17 are made of, for example, a conductive material (e.g., copper, gold, or aluminum). The connection terminals 17 each include, for example, a wire and a bonding pad. The connection terminals 17 electrically connect the one surface of the redistribution layer 15 and the first chip 16. For example, the connection terminals 17 electrically connect the redistribution layer 15 and the first chip 16 by way of wire bonding. The connection terminals 17 are provided for each of the stacked memories 161 of the first chip 16. The connection terminals 17 each electrically connects, for example, one stacked memory to the redistribution layer 15. In the present embodiment, the connection terminals 17 electrically connect one surface of the stacked memories 161 to the one surface of the redistribution layer 15.

The first mold portion 18 is constituted by, for example, a mold resin. The first mold portion 18 is disposed on the one surface of the redistribution layer 15. For example, the first mold portion 18 has a thickness greater than the height (thickness) of the first chip 16 and the height (thickness) of the connection terminals 17, with respect to the one surface of the redistribution layer 15. The first mold portion 18 covers the first chip 16 and the connection terminals 17 on the one surface of the redistribution layer 15. For example, in plan view, the first mold portion 18 has a rectangular shape conforming to the rectangular outer shape of the substrate 11.

Next, an operation of the semiconductor module 1 will be described. The semiconductor module 1 is configured such that electrical connection is established between the substrate 11 and an external electronic circuit via the solder balls 112. The second chip 12 is electrically connected to the external electronic circuit by being electrically connected to the substrate 11. The first chip 16 is electrically connected to the external electronic circuit by being electrically connected to the substrate 11 via the connection terminals 17, the redistribution layer 15, and the pillars 13.

Next, a method for manufacturing the semiconductor module 1 of the present embodiment will be described. The method for manufacturing the semiconductor module 1 includes a first chip disposing step, a connection terminal forming step, a first mold portion forming step, a redistribution layer forming step, a second chip disposing step, a pillar forming step, a second mold portion forming step, and a substrate disposing step.

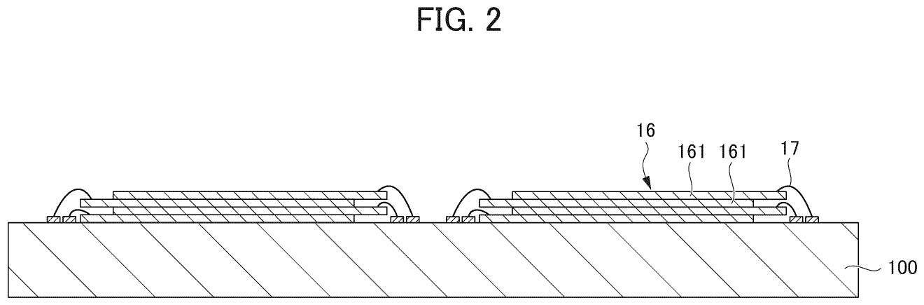

As illustrated in FIG. 2, in the first chip disposing step, a first chip 16 is disposed. Specifically, in the first chip disposing step, stacked memories are placed on top the other over a carrier substrate 100, thereby disposing the first chip 16.

In the connection terminal forming step, connection terminals 17 that are electrically connected to the first chip 16 are formed. In the connection terminal forming step, bonding pads are disposed on the carrier substrate 100. In addition, in the connection terminal forming step, the bonding pads and one surfaces of each of the stacked memories are connected using a wires.

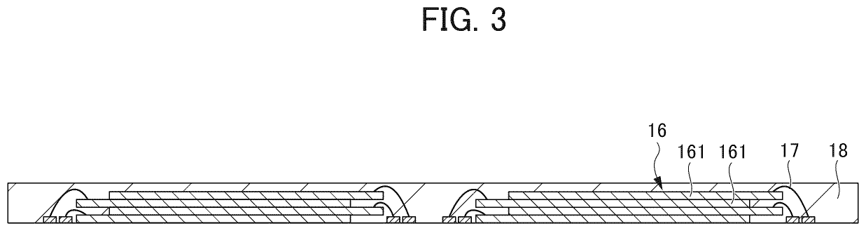

As illustrated in FIG. 3, in the first mold portion forming step, a first mold portion 18 is formed, which covers the connection terminals 17 and the first chip 16. In the first mold portion forming step, which is performed, for example, after the first chip disposing step and the connection terminal forming step, the first mold portion 18 is formed using a mold resin. Subsequently, the carrier substrate 100 is removed.

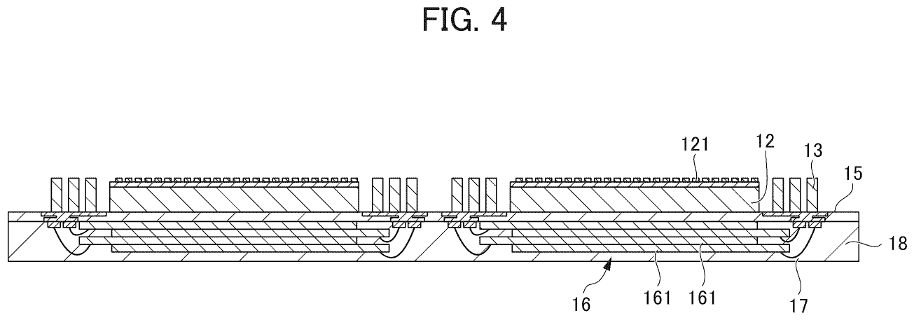

As illustrated in FIG. 4, in the redistribution layer forming step, a redistribution layer 15 is formed, which is disposed on one surface of the first chip 16 and will be electrically connected to the second chip 12. In the redistribution layer forming step, for example, the redistribution layer 15 is formed so as to be electrically connected to the connection terminals 17.

In the second chip disposing step, a second chip 12 is disposed on the other surface of the redistribution layer 15 opposite to the surface facing the first chip 16 at a position overlapping with the first chip 16 in the facing direction. In the second chip disposing step, the second chip 12 having terminal portions 121 on its surface (the other surface) facing away from the other surface of the redistribution layer 15 is disposed on the other surface of the redistribution layer 15. In the second chip disposing step, the second chip 12 is disposed in an out-of-plane direction of the redistribution layer 15, at the position overlapping with the first chip 16.

In the pillar forming step, pillars 13 are formed, which extend from the other surface of the redistribution layer 15. In the pillar forming step, the pillars 13 are formed at positions around the second chip 12 in the in-plane direction of the redistribution layer 15. In the pillar forming step of the present embodiment, the pillars 13 are formed around the second chip 12 such that the pillars 13 are arranged in pairs with the second chip 12 interposed therebetween in the in-plane direction of the redistribution layer 15.

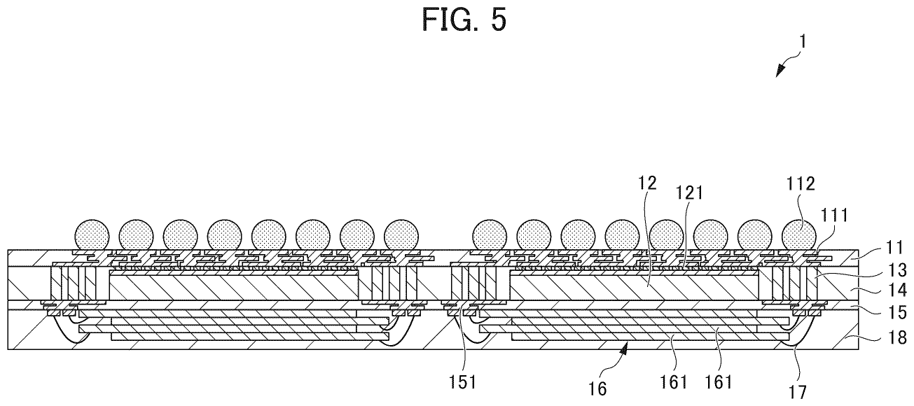

As illustrated in FIG. 5, in the second mold portion forming step, a second mold portion 14 is formed, which covers the second chip 12 and the pillars 13. In the second mold portion forming step, which is performed after the second chip disposing step and the pillar forming step, the second mold portion 14 is formed using a mold resin. Subsequently, the mold resin of the second mold portion 14 is ground so that the tips of the terminal portions 121 of the second chip 12 and the tips of the pillars 13 are exposed.

In the substrate disposing step, a substrate 11 is disposed, which is electrically connected to the pillars 13 and the second chip 12. The substrate 11 may be constituted by a redistribution layer. In the substrate disposing step, solder balls 112 are disposed on the other surface of the substrate 11. In the substrate disposing step, the terminal portions 121 of the second chip 12 and the pillars 13 are electrically connected to the one surface of the substrate 11.

Next, a flow of the method for manufacturing the semiconductor module 1 will be described. First, as illustrated in FIG. 2, the first chip disposing step is performed. Next, the connection terminal forming step is performed. Next, the first mold portion forming step is performed. Subsequently, as illustrated in FIG. 3, the carrier substrate 100 is removed.

Next, as illustrated in FIG. 4, in a state in which the other surface of the first chip 16 and the exposed portions (bonding pads) of the connection terminals 17 face upward, the redistribution layer forming step is performed. Next, the second chip disposing step is performed. Next, the pillar forming step is performed.

Next, as illustrated in FIG. 5, the second mold portion forming step is performed. Next, the substrate disposing step is performed. In this way, the semiconductor module 1 is manufactured.

The semiconductor module 1 and the method for manufacturing the same according to the first embodiment described above exert the following effects.
(1) A method for manufacturing a semiconductor module 1 including a plurality of chips, the method including: a first chip disposing step of disposing a first chip 16; a redistribution layer forming step of forming a redistribution layer 15, the redistribution layer 15 being disposed on one surface of the first chip 16 and electrically connected to a second chip 12, and having one surface facing the first chip 16; a second chip disposing step of disposing the second chip 12 at a position on the other surface of the redistribution layer 15 opposite to the one surface facing the first chip 16, the position overlapping with the first chip 16 in the facing direction; a pillar forming step of forming pillars 13 that extend from the other surface of the redistribution layer 15; and a substrate disposing step of disposing a substrate 11 that is electrically connected to the pillars 13 and the second chip 12. This feature makes it possible to provide the semiconductor module 1 having a form factor leading to a reduced thickness, in comparison with a case where either the first chip 16 or the second chip 12 is produced in a package. In addition, this feature enables manufactured at a wafer level, which allows for low-cost manufacture.

### Second Embodiment

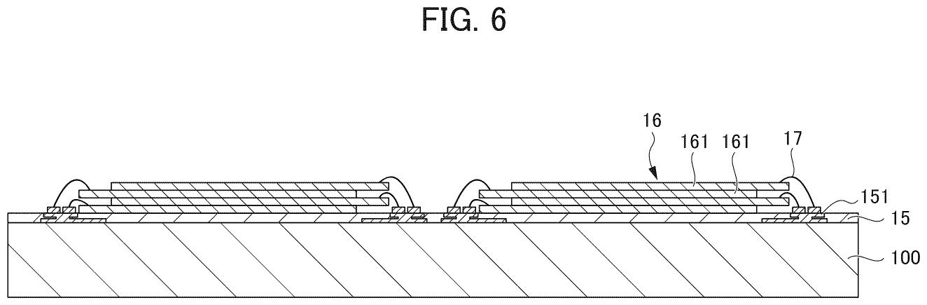

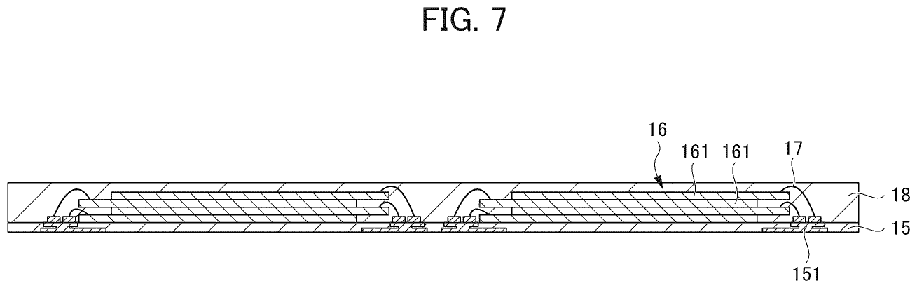

Next, a semiconductor module 1 and a method for manufacturing the same according to a second embodiment of the present invention will be described with reference to FIGS. 6 and 7. In the second embodiment, the same components as those of the first embodiment are denoted by the same reference numerals, and the description thereof is simplified or omitted. The method for manufacturing the semiconductor module 1 according to the second embodiment is different from that of the first embodiment in that a first chip disposing step is performed after a redistribution layer forming step in the second embodiment. Furthermore, the method for manufacturing the semiconductor module 1 according to the second embodiment is different from that of the first embodiment in that a second chip disposing step, a pillar forming step, and a substrate disposing step are performed after the first chip disposing step in the second embodiment.

First, as illustrated in FIG. 6, the redistribution layer forming step is performed on a carrier substrate 100. Next, the first chip disposing step and a connection terminal forming step are performed on one surface of the redistribution layer 15. Next, a first mold portion forming step is performed.

Next, as illustrated in FIG. 7, the carrier substrate 100 is removed. Next, as in the first embodiment, the second chip disposing step, the pillar forming step, a second mold portion forming step, and the substrate disposing step are performed.

The semiconductor module 1 and the method for manufacturing the same according to the second embodiment described above exert the following effects.
(2) The first chip disposing step is performed after the redistribution layer forming step, and the second chip disposing step, the pillar forming step, and the substrate disposing step are performed after the first chip disposing step. This feature makes it possible to facilitate the manufacture of the semiconductor module 1.

### Third Embodiment

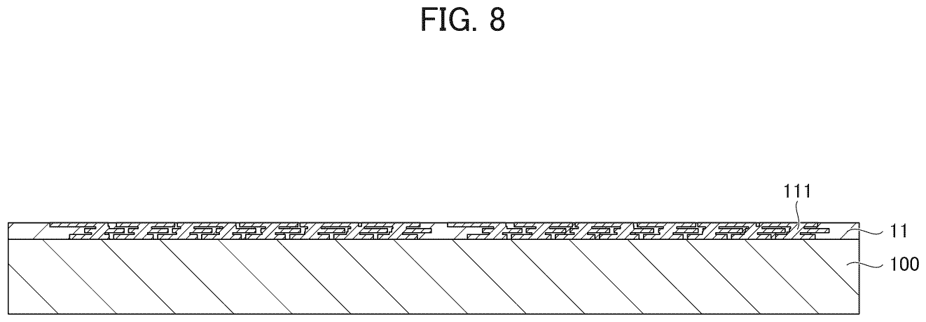

Next, a semiconductor module 1 and a method for manufacturing the same according to a third embodiment of the present invention will be described with reference to FIGS. 8 to 14. In the third embodiment, the same components as those of the first and second embodiments are denoted by the same reference numerals, and the description thereof is simplified or omitted. The method for manufacturing the semiconductor module 1 according to the third embodiment is different from those of the first and second embodiments in that a second chip disposing step and a pillar forming step are performed after a substrate disposing step in the third embodiment. Furthermore, the method for manufacturing the semiconductor module 1 according to the third embodiment is different from those of the first and second embodiments in that a redistribution layer forming step and a first chip disposing step are performed after the second chip disposing step and the pillar forming step in the third embodiment.

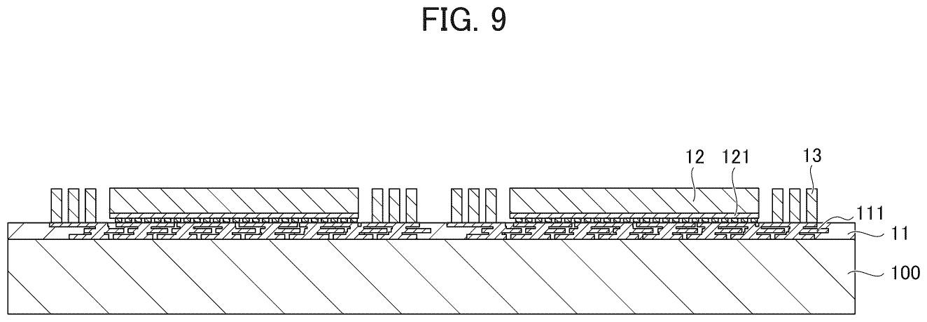

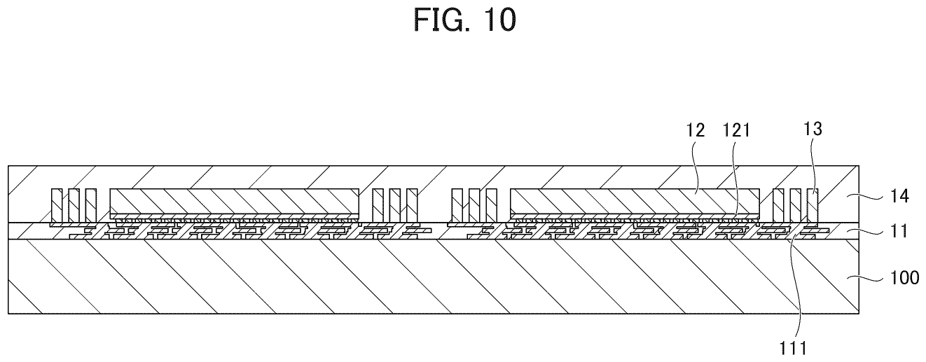

First, as illustrated in FIG. 8, the substrate disposing step is performed on a carrier substrate 100. The substrate 11 may be constituted by a redistribution layer. Next, as illustrated in FIG. 9, the second chip disposing step and the pillar forming step are performed on one surface of the substrate 11. Next, as illustrated in FIG. 10, a second mold portion forming step is performed. Subsequently, the mold resin of the second mold portion 14 is ground so that the tips of terminal portions 121 of the second chip 12 and the tips of the pillars 13 are exposed.

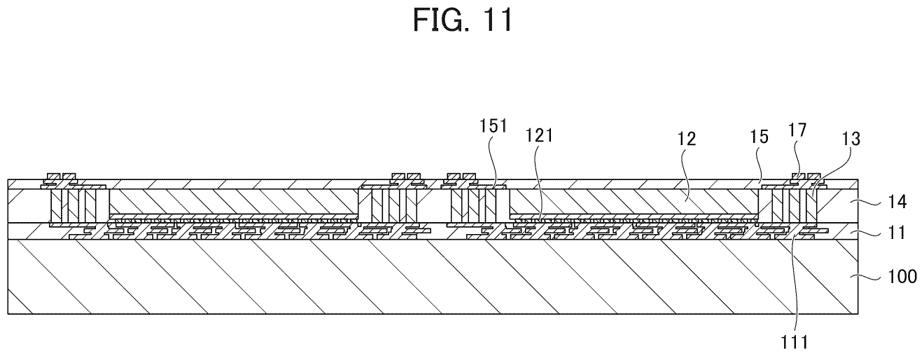

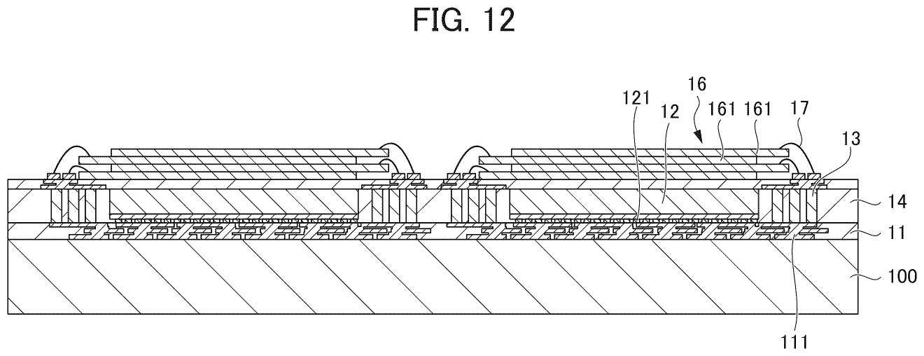

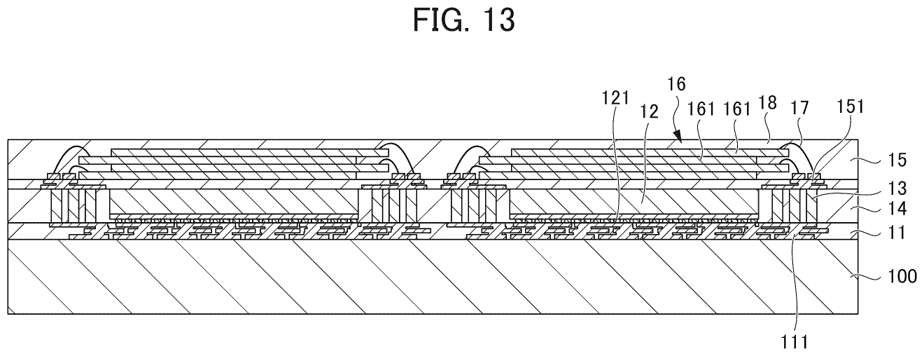

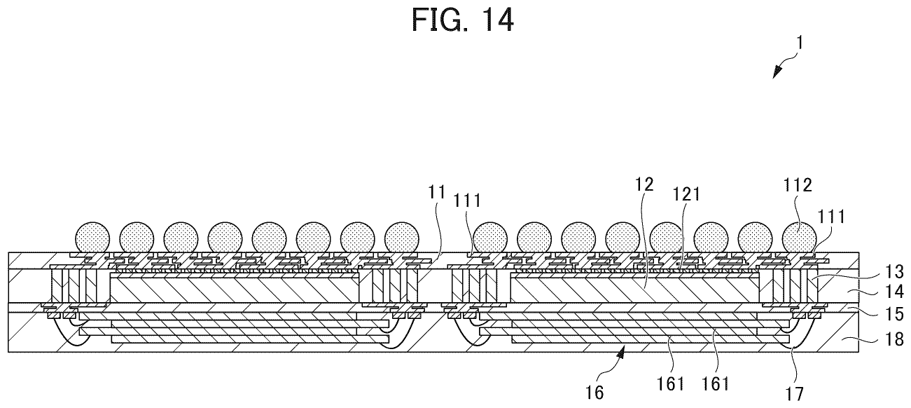

Next, as illustrated in FIG. 11, the redistribution layer forming step of forming a redistribution layer 15 on one surface of the substrate 11 is performed so that the pillars 13 and the second chip 12 are sandwiched between the redistribution layer 15 and the substrate 11. Next, as illustrated in FIG. 12, the first chip disposing step and a connection terminal forming step are performed on one surface of the redistribution layer 15. Next, as illustrated in FIG. 13, a first mold portion forming step is performed. Next, as illustrated in FIG. 14, the carrier substrate 100 is removed, and solder balls 112 are disposed on the other surface of the substrate 11. In this way, the semiconductor module 1 is manufactured.

The semiconductor module 1 and the method for manufacturing the same according to the third embodiment described above exerts the following effects.
(3) The second chip disposing step and the pillar forming step are performed after the substrate disposing step, and the redistribution layer forming step and the first chip disposing step are performed after the second chip disposing step and the pillar forming step. This feature makes it possible to facilitate the manufacture of the semiconductor module 1.

### Fourth Embodiment

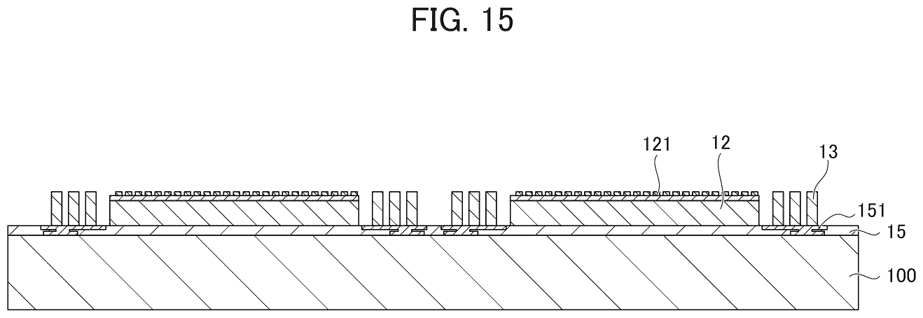

Next, a semiconductor module 1 and a method for manufacturing the same according to a fourth embodiment of the present invention will be described with reference to FIGS. 15 to 18. In the fourth embodiment, the same components as those of the first to third embodiments are denoted by the same reference numerals, and the description thereof is simplified or omitted. The semiconductor module 1 and the method for manufacturing the same according to the fourth embodiment are different from those of the first to third embodiments in that a second chip disposing step and a pillar forming step are performed after a redistribution layer formation step in the fourth embodiment. Furthermore, the semiconductor module 1 and the method for manufacturing the same according to the fourth embodiment are different from those of the first to third embodiments in that a first chip 16 forming step and a substrate disposing step are performed after the second chip disposing step and the pillar forming step in the fourth embodiment.

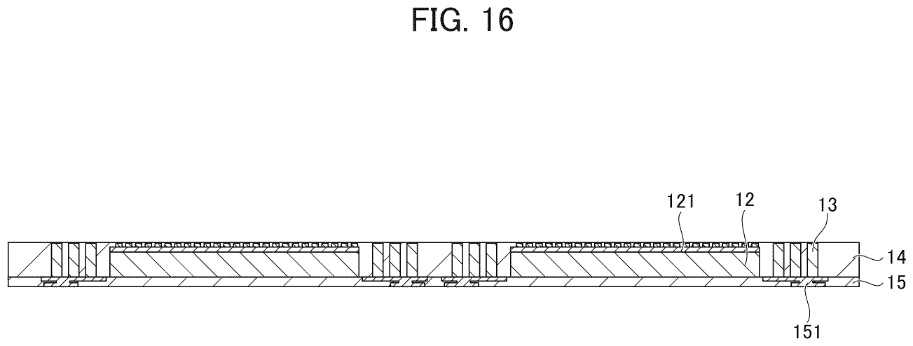

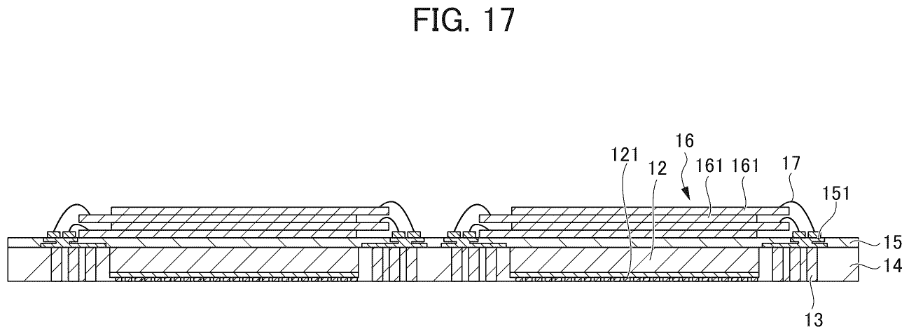

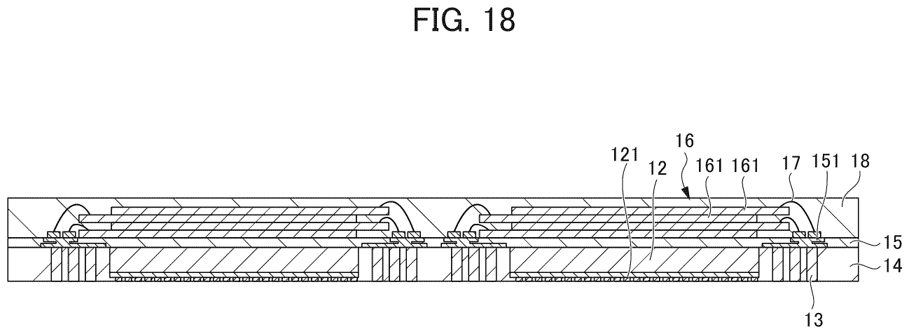

First, as illustrated in FIG. 15, the redistribution layer forming step is performed on a carrier substrate 100. Subsequently, the second chip disposing step and the pillar forming step are performed on the redistribution layer 15. Next, as illustrated in FIG. 16, a second mold portion forming step is performed. Next, the mold resin of the second mold portion 14 is ground so that the tips of terminal portions 121 of the second chip 12 and the tips of the pillars 13 are exposed. Subsequently, the carrier substrate 100 is removed. Next, as illustrated in FIG. 17, the first chip disposing step and a connection terminal forming step are performed on the redistribution layer 15 in a state in which the one surface of the redistribution layer 15 faces upward. Next, as illustrated in FIG. 18, a first mold portion forming step is performed. Next, in a state in which the other surface of the second chip 12 faces upward, the substrate disposing step is performed. In this way, the semiconductor module 1 is manufactured.

The semiconductor module 1 and the method for manufacturing the same according to the fourth embodiment described above exerts the following effects.
(4) The second chip disposing step and the pillar forming step are performed after the redistribution layer forming step, and the first chip 16 forming step and the substrate disposing step are performed after the second chip disposing step and the pillar forming step. This feature makes it possible to facilitate the manufacture of the semiconductor module 1.

In the foregoing, preferred embodiments of the semiconductor module and the method for manufacturing the same according to the present invention have been described. It should be noted that the present invention is not limited to the above-described embodiments and can be appropriately modified. For example, in the above embodiments, the method for manufacturing the semiconductor module 1 may include a singulation step of singulating a plurality of semiconductor modules 1. In the method for manufacturing the semiconductor module 1, the plurality of semiconductor modules 1 may be formed at a wafer level and then singulated. In the method for manufacturing the semiconductor module 1, the plurality of semiconductor modules 1 may be formed at a panel level and then singulated. Due to this feature, the plurality of semiconductor modules 1 can be efficiently manufactured.

Furthermore, the present invention is not limited to the above-described embodiments, in which the first chip 16 is the memory unit. The present invention is not limited to the above-described embodiments, in which the second chip 12 is the logic chip. The first chip 16 may be a logic chip, and the second chip 12 may be a memory unit. Moreover, the plurality of stacked memories 161 may be electrically connected by a through-silicon via (TSV). In this case, the plurality of stacked memories 161 may be electrically connected to the substrate 11 or the redistribution layer 15 by means of microbumps.

### EXPLANATION OF REFERENCE NUMERALS

1: Semiconductor module
11: Substrate
12: Second chip
13: Pillar
14: Second mold portion
15: Redistribution layer
16: First chip
17: Connection terminal
18: First mold portion
112: Solder ball

1. A method for manufacturing a semiconductor module including a plurality of chips, the method comprising:
a first chip disposing step of disposing a first chip;
a redistribution layer forming step of forming a redistribution layer, the redistribution layer being disposed on one surface of the first chip and having one surface facing the first chip;
a second chip disposing step of disposing a second chip at a position on an other surface of the redistribution layer opposite to the one surface facing the first chip, the position overlapping with the first chip in a facing direction;
a pillar forming step of forming a pillar that extends from the other surface of the redistribution layer; and
a substrate disposing step of disposing a substrate that is electrically connected to the pillar and the second chip.

2. The method for manufacturing a semiconductor module according to claim 1, wherein
the first chip disposing step is performed after the redistribution layer forming step, and the second chip disposing step, the pillar forming step, and the substrate disposing step are performed after the first chip disposing step.

3. The method for manufacturing a semiconductor module according to claim 1, wherein
the second chip disposing step and the pillar forming step are performed after the substrate disposing step, and
the redistribution layer forming step and the first chip disposing step are performed after the second chip disposing step and the pillar forming step.

4. The method for manufacturing a semiconductor module according to claim 1, wherein
the second chip disposing step and the pillar forming step are performed after the redistribution layer forming step, and
the first chip disposing step and the substrate disposing step are performed after the second chip disposing step and the pillar forming step.

5. The method for manufacturing a semiconductor module according to claim 1, further comprising:
a connecting step of electrically connecting the first chip and the redistribution layer, the connecting step being performed subsequent to the first chip disposing step.

6. The method for manufacturing a semiconductor module according to claim 5, wherein
the connecting step comprises wire bonding the first chip and the redistribution layer.

7. A semiconductor module with a plurality of chips, the semiconductor module comprising:
a substrate;
a second chip disposed on one surface of the substrate;
a pillar extending from the one surface of the substrate;
a redistribution layer disposed such that the second chip is interposed between the redistribution layer and the substrate, the redistribution layer being electrically connected to the pillar;
a first chip disposed on one surface of the redistribution layer opposite to an other surface facing the second chip, the first chip including a stacked memory; and
a connection terminal electrically connecting the one surface of the redistribution layer and the first chip.

8. The semiconductor module according to claim 7, wherein
the connection terminal comprises a bonding wire and a bonding pad.
